(19) United States
(12) Patent Application Publication
(10) Pub. No.: US 2024/0395680 A1
(43) Pub. Date: Nov. 28, 2024

(54) ANTI-WHISKER COUNTER MEASURE USING A METHOD FOR MULTIPLE LAYER PLATING OF A LEAD FRAME

(71) Applicant: STMicroelectronics S.r.l., Agrate Brianza (MB) (IT)

(72) Inventor: Paolo CREMA, Vimercate (IT)

(73) Assignee: STMicroelectronics S.r.l., Agrate Brianza (MB) (IT)

(21) Appl. No.: 18/797,031

(22) Filed: Aug. 7, 2024

Related U.S. Application Data
(62) Division of application No. 17/488,056, filed on Sep. 28, 2021.

(51) Int. Cl. H01L 23/495; H01L 21/56; H01L 23/00; H01L 23/31

(52) U.S. Cl. CPC H01L 23/49582; H01L 21/56; H01L 23/3107; H01L 23/49503; H01L 24/48; H01L 2224/48175

(57) ABSTRACT

A substrate of a lead frame is made of a first material. The substrate is covered by a barrier film made of a second material, different from the first material. The barrier film is then covered by a further film made of the first material. A first portion of the lead frame is encapsulated within an encapsulating body in a way which leaves a second portion of lead frame extending out from and not being covered by the encapsulating body. A first portion of the further film which is not covered by the encapsulating body is then stripped away to expose the barrier film at the second portion of the lead frame. A second portion of the further film is left remaining encapsulated by the encapsulating body. The exposed barrier film at the second portion of the lead frame is then covered with a tin or tin-based layer.

### CROSS REFERENCE TO RELATED APPLICATIONS

This application is a divisional of U.S. application for patent Ser. No. 17/488,056, filed Sep. 28, 2021, the disclosure of which is incorporated herein by reference.

### TECHNICAL FIELD

Embodiments herein relate to anti-whisker counter measures and, in particular, to a method for multiple layer plating of a lead frame to inhibit tin whisker growth.

### BACKGROUND

Tin whisker growth is a significant industrial concern in electronics. Historically, solder reflow techniques as well as the addition of lead to the tin electroplate served well to address the whisker growth concern. Recent legislation, however, has moved to ban the use of lead in electronics products, and as a result essentially pure tin plating is now being used. This again raises the issue of addressing tin whisker growth.

The selection of the material for the lead frame can have a significant impact on whisker formation. Copper is the typical, most widely used, material choice for the lead frame substrate. A layer of tin is then plated on the copper lead frame substrate. The driving force behind tin whisker formation is stress in this tin layer caused by the irregular growth of a Cu₆Sn₅ intermetallic when the tin film is plated directly on the copper lead frame substrate. Notably, this intermetallic forms easily at room ambient temperature levels.

Some mitigation of whisker growth can be obtained by applying a heat treatment after tin plating. The application of heat causes a bulk diffusion and results in the formation of a more regular and continuous intermetallic film consisting of both Cu₆Sn₅ and Cu₃Sn. As a result, stress level in the tin film layer is reduced. It is important that the heat treatment be applied immediately after the tin plating is performed.

Reference is now made to FIGS. 1A-1C which show steps of a prior art process (as taught, for example, in U.S. Pat. No. 7,931,760 and United States Patent Application Publication No. 2008/0316715, both of which are incorporated herein by reference). In FIG. 1A, a lead frame substrate 10 is made of copper or a copper alloy. A tin or tin-based film 12 is formed over the lead frame substrate 10 (for example, using an electroless deposition process). The film 12 has a preferred thickness. A thermal treatment is then applied at a desired temperature and for a desired length of time as a function of the preferred thickness in order to diffuse copper from the lead frame substrate 10 into the film 12. As an example, the desired temperature may be in the range of 90-160° C., and the desired length of time may be in the range of 30 to 90 minutes. Due to the film 12 having the preferred thickness, the applied thermal treatment converts substantially all (preferably, completely all) of the tin or tin-based film 12 into a stable copper-tin compound (Cu—Sn alloy) barrier film 14 as shown in FIG. 1B. As an example, the barrier film 14 may comprise Cu₃Sn. Next, a tin or tin-based film 16 is formed over the barrier film 14 as shown in FIG. 1C. The stability of the Cu₃Sn barrier film 14 prevents formation of uncontrolled intermetallic Cu₆Sn₅ growth, even in the presence of the overlying tin or tin-based film 16. As a result, tin whisker growth is inhibited.

It is also well known in the art that the use of one or more underlays (or material barriers) between the copper lead frame and the tin plating layer can be effective in mitigating formation and growth of tin whiskers. One particularly suitable material for use in the underlay is nickel. The presence of the nickel underlay prevents the formation of an irregular growth of the Cu₆Sn₅ intermetallic which is the stress-inducing precursor to the growth of whiskers.

Reference is now made to FIGS. 2A-2C which show steps of a prior art process (as taught, for example, in U.S. Pat. No. 5,780,172 and United States Patent Application Publication Nos. 2020/0388943, 2020/0187364 and 2002/0192492, incorporated herein by reference). In FIG. 2A, a lead frame substrate 20 is made of copper or a copper alloy. In FIG. 2B, an underlay comprising a nickel or nickel-based film 22 is formed over the lead frame substrate 20, for example, with a thickness of about 0.5-1.0 μm. Next, a tin or tin-based film 26 is formed over the nickel-based film 24 underlay as shown in FIG. 2C. The nickel-based film 24 forms a barrier layer blocking diffusion of tin into the copper lead frame substrate 20 and thus preventing formation of intermetallic Cu₆Sn₅ growth. As a result, tin whisker growth is inhibited.

### SUMMARY

In an embodiment, an electronic device comprises: a lead frame having a die pad portion and a plurality of lead portions, said lead frame including a substrate made of a first material, a barrier film made of a second material, different from the first material, covering the substrate at both the die pad portion and the plurality of lead portions, and a further film made of the first material covering the barrier film at both the die pad portion and at proximal ends of the plurality of lead portions, but where said further film does not cover the barrier film at distal ends of the plurality of lead portions; an integrated circuit chip mounted to the die pad portion of the lead frame and electrically connected to the proximal ends of the plurality of lead portions; an encapsulating body that encapsulates the integrated circuit chip, the die pad portion of the lead frame, and the proximal ends of the plurality of lead portions of the lead frame, but where said encapsulating body does not encapsulate the distal ends of the plurality of lead portions, with said further film being covered by said encapsulating body; and a tin or tin-based layer covering the barrier film at the distal ends of the plurality of lead portions which are not covered by said encapsulating body.

In an embodiment, an electronic device comprises: a lead frame; and an encapsulating body that encapsulates a first portion of the lead frame but does not encapsulate a second portion of the lead frame which extends out from and is not covered by said encapsulating body. Said lead frame comprises: a substrate made of a first material; a barrier film made of a second material, different from the first material, covering the substrate at both the first and second portions of the lead frame; a further film made of the first material covering the barrier film only at the first portion of the lead frame; and a tin or tin-based layer covering the barrier film at the second portion of the lead frame which extends out from and is not covered by said encapsulating body.

In an embodiment, a method comprises: forming a substrate of a lead frame, said substrate being made of a first material; covering the substrate with a barrier film made of a second material, different from the first material; covering the barrier film with a further film made of the first material; encapsulating a first portion of the lead frame within an encapsulating body so as to leave a second portion of lead frame extending out from and not being covered by said encapsulating body; stripping a first portion of the further film not being covered by said encapsulating body to expose the barrier film at the second portion of the lead frame, while leaving a second portion of the further film remaining encapsulated by the encapsulating body; and covering the exposed barrier film at the second portion of the lead frame with a tin or tin-based layer.

### BRIEF DESCRIPTION OF THE DRAWINGS

For a better understanding of the embodiments, reference will now be made by way of example only to the accompanying figures in which:

FIGS. 1A-1C show steps of a prior art process for treating a lead frame for inhibiting growth of whiskers;

FIGS. 2A-2C show steps of a prior art process for treating a lead frame for inhibiting growth of whiskers;

FIGS. 3A-3H show steps of a process for manufacturing an electronic device; and

FIGS. 4A-4D shown alternative steps of the process for manufacturing.

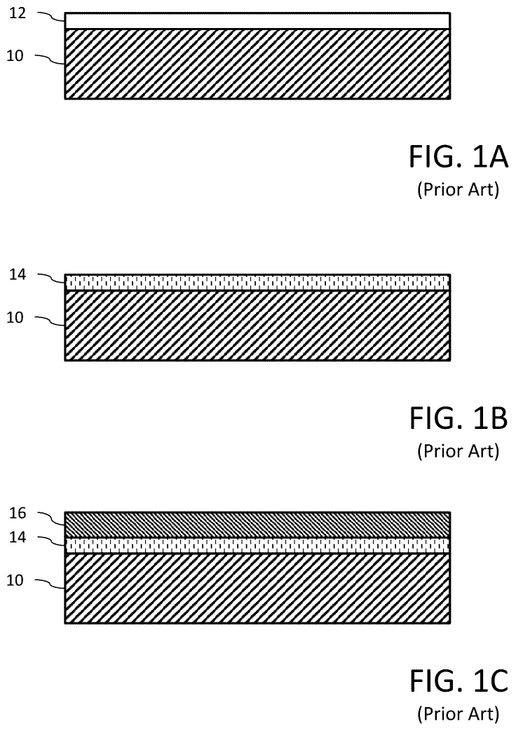

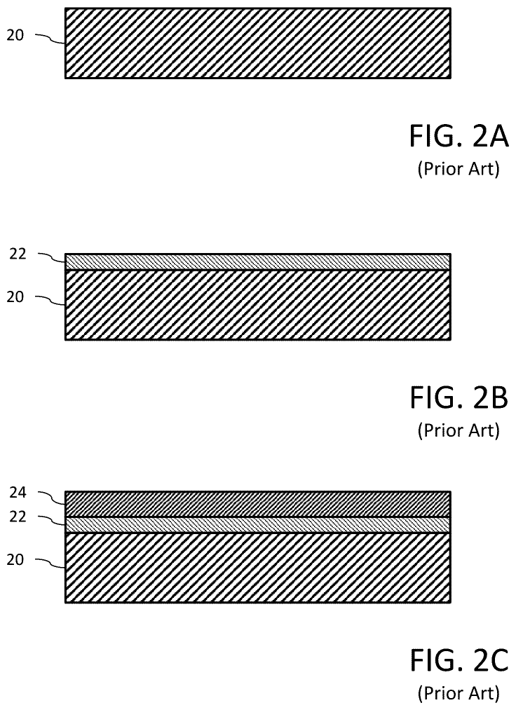

It will be noted that the drawings are not necessarily presented to scale, and some exaggeration of sizes, shapes, thicknesses, etc., has been made in order ease understanding of the illustrated structures.

### DETAILED DESCRIPTION OF THE DRAWINGS

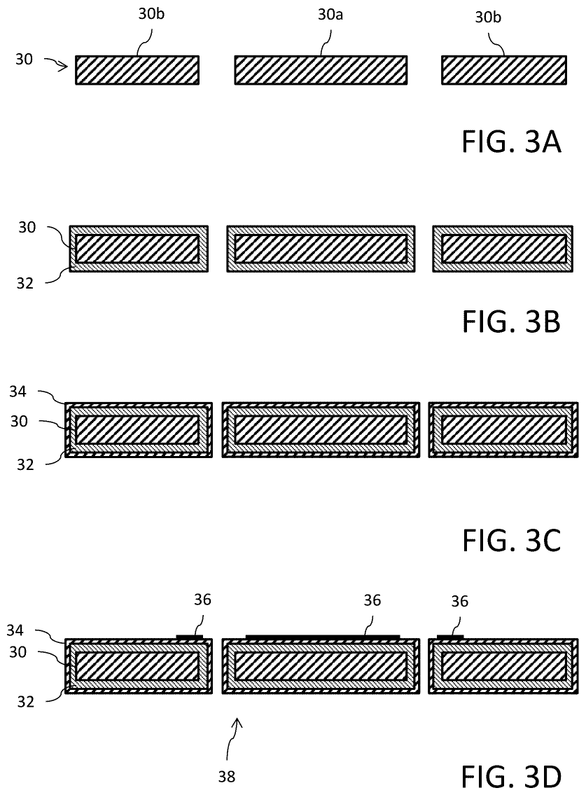

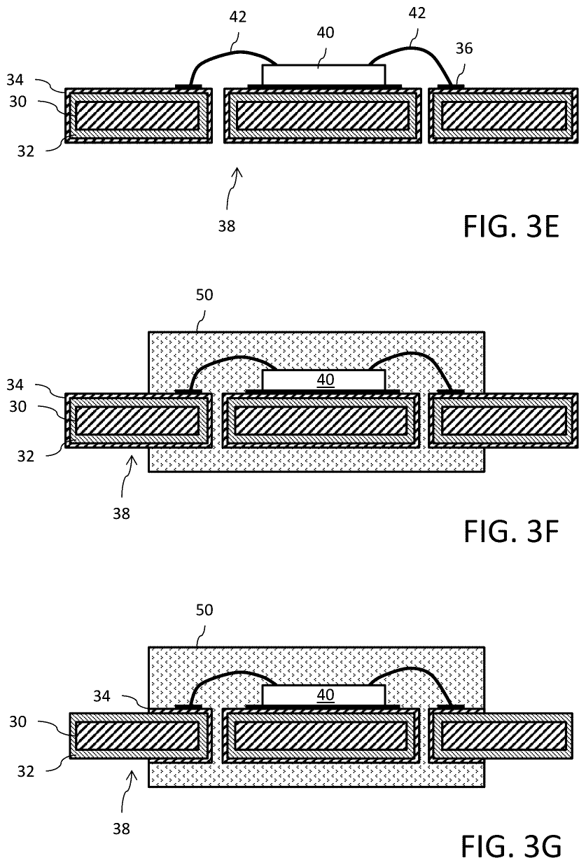

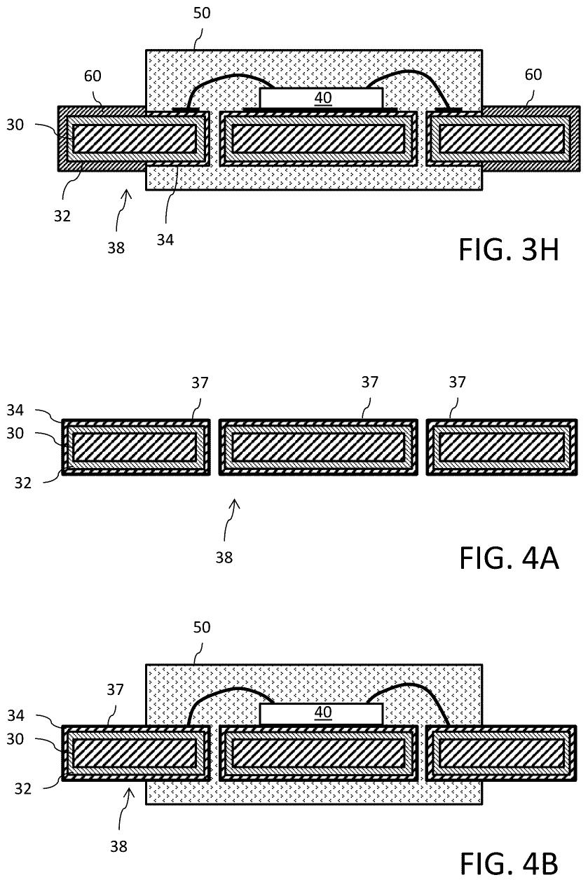

Reference is made to FIGS. 3A-3H which show steps of a process for manufacturing an electronic device. In FIG. 3A, a substrate 30 for a lead frame is made of copper or a copper-based alloy and is formed using conventional fabrication techniques such as stamping to provide a die pad portion 30a and a plurality of lead portions 30b. The lead frame substrate 30 is then fully plated with an underlay comprising a nickel or nickel-based film 32 as shown in FIG. 3B. The nickel or nickel-based film 32 may have a thickness, for example, in a range from 0.5 to 3.0 μm and more preferably in a range from 0.5 to 1.0 μm. In an embodiment, the underlay film 32 may instead be made of a different barrier material such as silver, for example. Alternatively, the film 32 may be formed of multiple layers in a stack. Next, a copper or copper-based film 34 is plated on the nickel or nickel-based film 32 as shown in FIG. 3C in order to isolate the nickel or nickel-based film 32 from the atmosphere and protect against the formation of an undesirable nickel oxide. The copper or copper-based film 34 may have a thickness, for example, in a range from 1.0 to 10.0 μm. If necessary, or desired, a layer of silver (or silver-based material) may be spot plated at certain locations to the copper or copper-based film 34. The spots 36 of silver are preferably provided at the die pad portion 30a and at the proximal ends of the plurality of lead portions 30b of the lead frame. The result is shown in FIG. 3D. The layer of silver for the spots 36 may have a thickness, for example, in a range from 2.0 to 4.0 μm, and more preferably is about 3.0 μm thick. The steps 3A-3D may, for example, be performed by a manufacturer of the lead frame 38.

In FIG. 3E, an integrated circuit chip 40 has been mounted at the die pad portion 30a of the lead frame 38. Furthermore, bonding wires 42 have been installed to electrically connect pads (not explicitly shown) of the integrated circuit chip 40 to the proximal ends of the plurality of lead portions 30b of the lead frame 38. More specifically, the integrated circuit chip 40 is attached to the spot 36 of silver at the die pad portion 30a and the distal ends of the bonding wires 42 are attached to the spots 36 of silver at the proximal ends of the plurality of lead portions 30b.

Using a conventional transfer molding process well known to those skilled in the art, an encapsulating body 50 made of resin is molded around the integrated circuit chip 40, the bonding wires 42, the die pad portion 30a of the lead frame 38 and the proximal ends of the plurality of lead portions 30b of the lead frame 38. The result is shown in FIG. 3F. In this context, the die pad portion 30a of the lead frame 38 and the proximal ends of the plurality of lead portions 30b of the lead frame 38 form a first portion of the lead frame which is encapsulated by the encapsulating body, and the distal ends of the plurality of lead portions 30b of the lead frame 38 form a second portion of the lead frame which is not encapsulated by the encapsulating body. In an alternative embodiment, the molding process may be configured so that the bottom surface of the die pad portion 30a of the lead frame 38 is exposed from the encapsulating body 50.

Next, the portion of the copper or copper-based film 34 on the plurality of lead portions 30b of the lead frame 38 which is exposed outside of the encapsulating body 50 (i.e., at the distal ends of the plurality of lead portions 30b associated with the second portion of the lead frame) is selectively stripped away. The result is shown in FIG. 3G. This copper stripping operation may, for example, be performed using an immersion process which selectively removes the exposed copper without damaging the encapsulating body 50. As an example, an immersion stripper using a combination of Sulfuric acid and Hydrogen peroxide can be used. Alternatively, an electro-stripping process may be used with an Anodic current application. As an example, the electro-strip solution may include a combination of Sulfuric acid and Copper sulfate. The copper stripping operation has little to no effect on the nickel or nickel-based film 32 underlay, which remains in place covering the copper substrate 30, and does not have an adverse effect on the resin material forming the encapsulating body 50.

A tin or tin-based film 60 is then formed over the nickel or nickel-based film 32 underlay on the plurality of lead portions 30b located outside of the encapsulating body 50 (i.e., in association with the second portion of the lead frame) as shown in FIG. 3H. The underlay of the nickel or nickel-based film 32 forms a barrier layer blocking diffusion of tin into the copper substrate 30 of the lead frame 38 in order to prevent formation of intermetallic Cu₆Sn₅ growth. As a result, tin whisker growth is inhibited. In an embodiment, the film 60 may, for example, have a thickness on the order of a few μm (such as, a thickness in a range from 0.5 μm to 5.0 μm, or about the same thickness as the stripped copper or copper-based film 34).

In a preferred implementation of the method, the formation of the tin or tin-based film 60 utilizes a “wet-to-wet” process where the nickel or nickel-based film 32 is not exposed to atmosphere following the selectively stripping of the copper or copper-based film 34. The advantage of this processing technique is an improved adhesion of the tin or tin-based film 60 to the nickel or nickel-based film 32. More specifically, it is noted that an undesirable oxide can form on the nickel film 32 if exposed to atmosphere, and this oxide can be difficult to remove and furthermore, if present, forms a barrier which inhibits effective tin or tin-based film 60 adhesion and increases the risk of peel off.

Further processing steps such as cutting, bending and/or shaping the distal ends of the plurality of lead portions 30b for the second portion of the lead frame, not explicitly shown but well known to those skilled in the art, can then be performed to complete manufacture of the electronic device product.

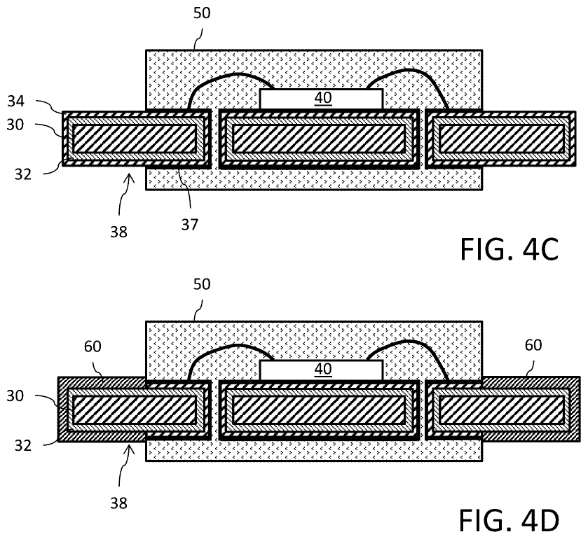

With reference once again to FIG. 3D, instead of performing a spot plating of the silver, a full plate deposit of silver forming silver film 37 can instead be made with a result as shown in FIG. 4A. FIG. 4B shows the structure after completion of the molding process (see, FIG. 3F) to form the encapsulating body 50. Next, the portion of the silver film 47 on the plurality of lead portions 30b of the lead frame 38 which is exposed outside of the encapsulating body 50 (i.e., at the distal ends of the plurality of lead portions 30b associated with the second portion of the lead frame) is selectively stripped away. The result is shown in FIG. 4C. This silver stripping operation may, for example, be performed using a methane sulphonic acid treatment which is selective as to the silver film 47 relative to the underlying copper or copper-based film 34 and furthermore has no adverse effect on the resin material forming the encapsulating body 50. The process then continues with the steps as shown in FIGS. 3G and 3H where the copper or copper-based film 34 is selectively stripped and the tin or tin-based film 60 is then deposited at the second portion of the lead frame outside of the encapsulating body. The resulting electronic device product is shown in FIG. 4D.

As used herein, the terms “substantially,” “approximately,” or “on the order of” are used to designate a tolerance of plus or minus 10%, more preferably 5%, of the value in question.

The foregoing description has provided by way of exemplary and non-limiting examples of a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A method, comprising:
forming a substrate of a lead frame, said substrate being made of a first material;
covering all of the substrate with a barrier film made of a second material, different from the first material;
covering all of the barrier film with a further film made of the first material;
encapsulating a first portion of the lead frame within an encapsulating body so as to leave a second portion of lead frame extending out from and not being covered by said encapsulating body;
stripping a first portion of the further film that is not covered by said encapsulating body to expose the barrier film at the second portion of the lead frame, while leaving a second portion of the further film remaining encapsulated by the encapsulating body; and
covering the exposed barrier film at the second portion of the lead frame with a tin or tin-based layer.

2. The method of claim 1, wherein said first material is a copper or copper-based material.

3. The method of claim 1, wherein said second material is a nickel or nickel-based material.

4. The method of claim 1, wherein said first portion of the lead frame includes a die pad portion for the lead frame.

5. The method of claim 1, wherein said first portion of the lead frame includes a proximal end portion of each lead for the lead frame.

6. The method of claim 5, wherein encapsulating comprises embedding an integrated circuit chip within the encapsulating body.

7. The method of claim 6, further comprising electrically connecting said integrated circuit chip to the proximal end portion of each lead for the lead frame.

8. The method of claim 1, further comprising, before encapsulating, forming a layer made of a third material, different from the first and second materials, on the further film.

9. The method of claim 8, further comprising stripping a first portion of the layer made of the third material that is not covered by said encapsulating body to expose the further film at the second portion of the lead frame, while leaving a second portion of the layer made of the third material remaining encapsulated by the encapsulating body.

10. The method of claim 9, wherein said third material is a silver or silver-based material.

11. The method of claim 8, wherein forming the layer made of the third material comprises spot forming said layer at locations at said first portion of the lead frame.

12. A method, comprising:
forming a substrate of a lead frame, said substrate being made of a first material;
covering the substrate with a barrier film made of a second material, different from the first material; and
covering the barrier film with a further film made of the first material.

13. The method of claim 12, wherein said first material is a copper or copper-based material.

14. The method of claim 12, wherein said second material is a nickel or nickel-based material.

15. The method of claim 12, further comprising forming a layer made of a third material, different from the first and second materials, covering at least part of the further film.

16. The method of claim 15, wherein said third material is a silver or silver-based material.

17. The method of claim 15, wherein forming the layer made of the third material comprises spot forming said layer at a die pad portion of the lead frame.

18. The method of claim 15, wherein forming the layer made of the third material comprises spot forming said layer at proximal ends of plurality of lead portions of the lead frame.
